(19) United States
(12) Patent Application Publication
(10) Pub. No.: US 2026/0358696 A1
(43) Pub. Date: Nov. 12, 2026

(54) PELLICLE STRUCTURE FOR EUV LITHOGRAPHY AND METHODS OF MANUFACTURING THEREOF

(71) Applicant: Taiwan Semiconductor Manufacturing Company, Ltd., Hsinchu (TW)

(72) Inventors: Pei-Cheng HSU, Taipei (TW); Hsin-Chang LEE, Zhubei (TW)

(73) Assignee: Taiwan Semiconductor Manufacturing Company, Ltd., Hsinchu (TW)

(21) Appl. No.: 19/745,047

(22) Filed: Jul. 16, 2026

Related U.S. Application Data
(63) Continuation of application No. 18/766,358, filed on Jul. 8, 2024.
(60) Provisional application No. 63/636,381, filed on Apr. 19, 2024.

(51) Int. Cl. G03F 1/62

(52) U.S. Cl. CPC G03F 1/62

(57) ABSTRACT

A method of forming a pellicle includes growing carbon nanotubes (CNTs), wrapping the CNTs with one or more nanotubes made of a different material, and removing the CNTs. The CNTs can be grown over a filter and the filter can be subsequently removed. The CNTs can be contacted with a frame. The different materials include one or more of boron nitride, hexagonal boron nitride (h-BN), SiC, MoS₂, MoSe₂, WS₂, WSe₂, SnS₂, SnS, ZrO₂, ZrO, and TiO₂.

### RELATED APPLICATIONS

This application is a continuation application of U.S. patent application Ser. No. 18/766,358 filed Jul. 8, 2024, which claims priority of U.S. Provisional Patent Application No. 63/636,381 filed Apr. 19, 2024, the entire content of each of which is incorporated herein by reference.

### BACKGROUND

A pellicle is a thin transparent film stretched over a frame that is glued over a photomask to protect the photomask from damage, dust and/or moisture. In extreme ultraviolet (EUV) lithography, a pellicle having a high transparency in the EUV wavelength region, a high mechanical strength and a low or no contamination is generally applied.

### BRIEF DESCRIPTION OF THE DRAWINGS

Aspects of the present disclosure are best understood from the following detailed description when read with the accompanying figures. It is noted that, in accordance with the standard practice in the industry, various features are not drawn to scale. In fact, the dimensions of the various features may be arbitrarily increased or reduced for clarity of discussion.

FIGS. 1A and 1B show nanotubes and pellicles for an EUV photomask in accordance with embodiments of the present disclosure.

FIGS. 2A, 2B, 2C, and 2D show various views of multiwall nanotubes in accordance with embodiments of the present disclosure.

FIGS. 3A, 3B, and 3C show process stages for manufacturing a pellicle for an EUV photomask in accordance with an embodiment of the present disclosure.

FIG. 4 shows a process stage for manufacturing a pellicle for an EUV photomask in accordance with an embodiment of the present disclosure.

FIGS. 5A and 5B show a cross sectional view and a plan (top) view of one of the various stages for manufacturing a pellicle for an EUV photomask in accordance with an embodiment of the present disclosure.

FIGS. 6A and 6B show a cross sectional view and a plan (top) view of one of the various stages for manufacturing a pellicle for an EUV photomask in accordance with an embodiment of the present disclosure.

FIGS. 7A, 7B, 7C, 7D, and 7E show a process flow for various stages for manufacturing a pellicle for an EUV photomask in accordance with embodiments of the present disclosure.

FIGS. 8A, 8B, 8C, and 8D show a process flow for various stages for manufacturing a pellicle for an EUV photomask in accordance with embodiments of the present disclosure.

FIG. 9A shows a process stage for manufacturing a pellicle for an EUV photomask in accordance with an embodiment of the present disclosure. FIG. 9B shows nanotube structures produced by the process stage.

FIGS. 10A and 10B show forming wrapping layers over the bundles of nanotubes in accordance with an embodiment of the present disclosure.

FIG. 11A shows a process stage for manufacturing a pellicle for an EUV photomask in accordance with an embodiment of the present disclosure. FIG. 11B shows nanotube structures produced by the process stage.

FIGS. 12A, 12B, and 12C show nanotube structures produced by manufacturing processes according to embodiments of the disclosure.

FIGS. 13A and 13B show forming bonded bundles of nanotubes according to an embodiment of the present disclosure.

FIG. 14 shows a structure of a membrane of a pellicle for an EUV photomask in accordance with embodiments of the present disclosure.

FIG. 15 shows a structure of a membrane of a pellicle for an EUV photomask in accordance with embodiments of the present disclosure.

FIG. 16 shows a structure of a membrane of a pellicle for an EUV photomask in accordance with embodiments of the present disclosure.

FIG. 17 shows a structure of a membrane of a pellicle for an EUV photomask in accordance with embodiments of the present disclosure.

FIGS. 18A, 18B, 18C, 18D, 18E, 18F, 18G, 18H, 18I, 18J, 18K, 18L, 18M, 18N, and 18O are illustrations of transmission electron microscopy (TEM) images of membrane structures according to embodiments of the present disclosure.

FIG. 19 shows a flowchart of a method of manufacturing a pellicle for an EUV photomask in accordance with an embodiment of the present disclosure.

FIG. 20 shows a flowchart of a method of manufacturing a pellicle for an EUV photomask in accordance with an embodiment of the present disclosure.

FIG. 21 shows a flowchart of a method of manufacturing a pellicle for an EUV photomask in accordance with an embodiment of the present disclosure.

FIG. 22A shows a flowchart of a method making a semiconductor device, and FIGS. 22B, 22C, 22D, and 22E show a sequential manufacturing operation of a method of manufacturing a semiconductor device according to embodiments of present disclosure.

### DETAILED DESCRIPTION

It is to be understood that the following disclosure provides many different embodiments, or examples, for implementing different features of the invention. Specific embodiments or examples of components and arrangements are described below to simplify the present disclosure. These are, of course, merely examples and are not intended to be limiting. For example, dimensions of elements are not limited to the disclosed range or values, but may depend upon process conditions and/or desired properties of the device. Moreover, the formation of a first feature over or on a second feature in the description that follows may include embodiments in which the first and second features are formed in direct contact, and may also include embodiments in which additional features may be formed interposing the first and second features, such that the first and second features may not be in direct contact. Various features may be arbitrarily drawn in different scales for simplicity and clarity. In the accompanying drawings, some layers/features may be omitted for simplification.

Further, spatially relative terms, such as “beneath,” “below,” “lower,” “above,” “upper” and the like, may be used herein for ease of description to describe one element or feature's relationship to another element(s) or feature(s) as illustrated in the figures. The spatially relative terms are intended to encompass different orientations of the device in use or operation in addition to the orientation depicted in the figures. The device may be otherwise oriented (rotated 90 degrees or at other orientations) and the spatially relative descriptors used herein may likewise be interpreted accordingly. In addition, the term “made of” may mean either “comprising” or “consisting of.” Further, in the following fabrication process, there may be one or more additional operations in between the described operations, and the order of operations may be changed. In the present disclosure, the phrase “at least one of A, B and C” means either one of A, B, C, A+B, A+C, B+C or A+B+C, and does not mean one from A, one from B and one from C, unless otherwise explained. Materials, configurations, structures, operations and/or dimensions explained with one embodiment can be applied to other embodiments, and detained description thereof may be omitted.

EUV lithography is one of the crucial techniques for extending Moore's law. However, due to wavelength scaling from 193 nm (ArF) to 13.5 nm, the EUV light source suffers from strong power decay due to environmental adsorption. Even though a stepper/scanner chamber is operated under vacuum to prevent strong EUV adsorption by gas, maintaining a high EUV transmittance from the EUV light source to a wafer is still an important factor in EUV lithography.

A pellicle generally requires a high transparency and a low reflectivity. In ultraviolet (UV) or deep UV (DUV) lithography, the pellicle film is made of a transparent resin film. In EUV lithography, however, a resin-based film would not be acceptable, and a non-organic material, such as a polysilicon, silicide, or metal film, is used in some embodiments.

One of the EUV production performance bottlenecks is EUV mask pellicle failure, such as distortion, cracking, and breaking.

Carbon nanotubes (CNTs) are one of the materials suitable for a pellicle for an EUV photomask because CNTs have a high EUV transmittance of more than 96.5%. Generally, a pellicle for an EUV reflective mask requires the following properties: (1) Long life time in a hydrogen radical rich operation environment in an EUV stepper/scanner; (2) Strong mechanical strength to minimize the sagging effect during vacuum pumping and venting operations; (3) A high or perfect blocking property for particles larger than about 20 nm (killer particles); and (4) Good heat dissipation to prevent the pellicle from being burnt out by EUV radiation.

However, the strong CNT sp2 bond can easily be etched in the EUV scanner environment by EUV-induced hydrogen and oxygen plasma. Protective coatings for CNT include amorphous films. However, the amorphous films can also easily be etched in the EUV scanner environment, which lowers the usefulness of the protective coating. CNT non-uniformity may also be a problem. The non-uniformity may result in poor pattern imaging by poor EUVT (EUV transmittance) and/or poor EUVR (EUV reflectivity).

In addition, the pellicle temperature increases with increasing EUV power. For example, the temperature of the pellicle may be in the range of 527±50 °C when the EUV power is 436±20 W. CNT pellicles may not be able to withstand such high temperatures, since they are only thermal stable up to a range of about 500 to 700 °C.

Pellicles formed of inorganic materials other than elemental carbon-based materials or ceramics can be operated at higher temperatures because they are thermally stable up to about 800 to 900 °C. A pellicle formed from an inorganic or ceramic material, such as a boron nitride nanotube (BNNT), has higher thermal stability than a pellicle formed from CNTs.

Some inorganic or ceramic nanotube deposition methods produce short and poor-quality nanotubes, making it quite difficult to form a free-standing pellicle. However, in this disclosure, a method that provides high transmittance, high strength EUV pellicles is disclosed. According to some embodiments of the present disclosure, using single or double wall carbon nanotubes CNTs, a free-standing pellicle is formed as a template. Then inorganic or ceramic nanotubes made of a different material than the CNTs wrap around the CNT to create a core-shell structure. The CNTs can be partially or completely removed through heating after forming the shell structure.

In some embodiments of the present disclosure, a nanotube is a one-dimensional elongated tube having a dimeter in a range from about 0.5 nm to about 100 nm.

In the present disclosure, a pellicle for an EUV photomask includes a network membrane having a plurality of nanotubes that form a mesh structure. Further, a method of producing the pellicle having increased mechanical strength and increased EUV transmittance is also disclosed.

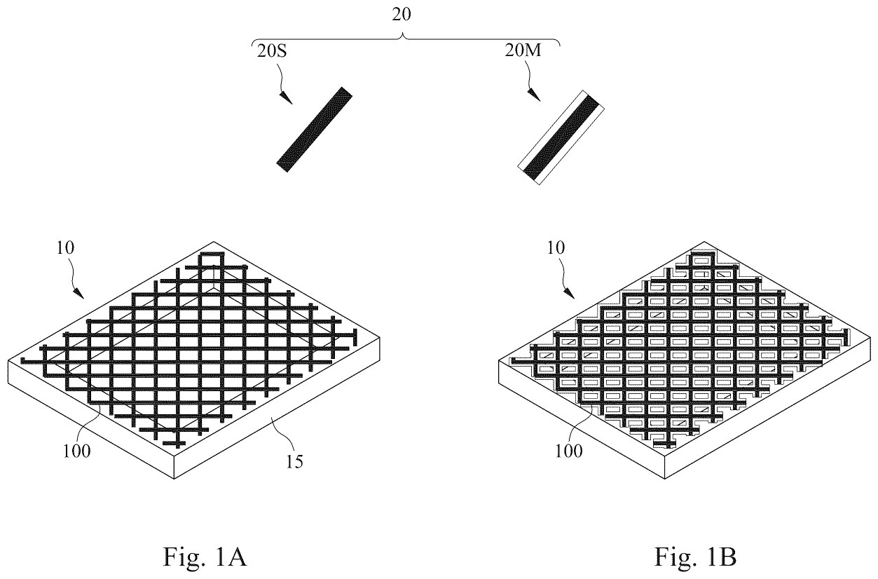

FIGS. 1A and 1B show EUV pellicles 10 in accordance with an embodiment of the present disclosure. In some embodiments, a pellicle 10 for an EUV reflective mask includes a main network membrane 100 disposed over and attached to a pellicle frame 15. In some embodiments, the main network membrane 100 is a transparent membrane transparent to electromagnetic radiation, such as EUV radiation. In some embodiments, the transparent membrane 100 has an EUV transmittance of more than 96.5%. The transparent membrane 100 may be opaque to some electromagnetic wavelengths, such as infrared or visible radiation and transparent to other electromagnetic wavelengths, such as EUV radiation or X-ray radiation. In some embodiments, as shown in FIG. 1A, the main network membrane 100 includes a plurality of nanotubes 20, such as single wall nanotubes 20S, and in other embodiments, as shown in FIG. 1B, the nanotubes 20 making up the main network membrane 100 includes a plurality of multiwall nanotubes 20M. In some embodiments, the single wall nanotubes are non-elemental carbon-based nanotubes. In some embodiments, the non-elemental carbon-based material includes at least one of boron nitride (BN) including hexagonal boron nitride (h-BN), SiC or transition metal dichalcogenides (TMDs), represented by MX₂, where M=Mo, W, Pd, Pt, Sn, and/or Hf, and X═S, Se and/or Te. In some embodiments, the TMD is one of MoS₂, MoSe₂, WS₂ or WSe₂. In other embodiments, the non-elemental carbon-based material is an inorganic material or a ceramic. In some embodiments, the inorganic material includes at least one of SnS, ZrO₂, ZrO, or TiO₂.

In some embodiments, the nanotubes bond or attach to each other to form a bundle of nanotubes.

In some embodiments, a multiwall nanotube is a coaxial nanotube having one or more walls coaxially surrounding an inner tube(s). In some embodiments, the main network membrane 100 includes only one type of nanotube (e.g.—single wall or multiwall or single material) and in other embodiments, different types of nanotubes form the main network membrane 100. In some embodiments, the multiwall nanotubes are multiwall inorganic or ceramic nanotubes. In some embodiments, some of the multiwall nanotubes form a bundle of nanotubes attached to each other.

In some embodiments, a pellicle (support) frame or border 15 is attached to the main network membrane 100 to maintain a space between the main network membrane of the pellicle and an EUV mask (pattern area) when mounted on the EUV mask. The pellicle frame 15 of the pellicle is attached to the surface of the EUV photomask with an appropriate bonding material. In some embodiments, the bonding material is an adhesive, such as an acrylic or silicon-based glue or a cross link type adhesive. The size of the frame structure is larger than the area of the black borders of the EUV photomask so that the pellicle covers not only the circuit pattern area of the photomask but also the black borders.

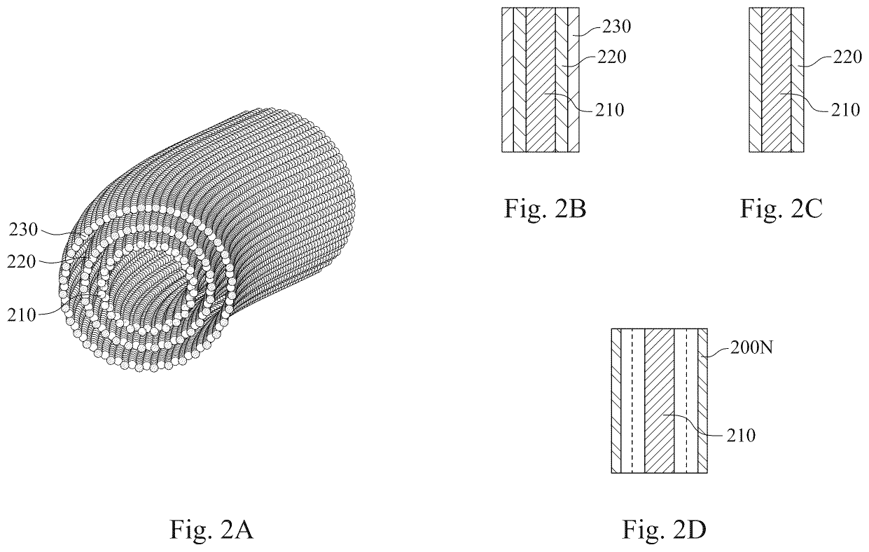

FIGS. 2A, 2B, 2C, and 2D show various views of multiwall nanotubes in accordance with embodiments of the present disclosure.

In some embodiments, the nanotubes in the main network membrane 100 include multiwall nanotubes, which are also referred to as coaxial nanotubes. FIG. 2A shows a perspective view of a multiwall coaxial nanotube having three tubes 210, 220, and 230 and FIG. 2B shows a cross sectional view thereof. In some embodiments, the inner tube 210 and outer tubes 220 and 230 are non-carbon-based nanotubes, such as boron nitride nanotubes.

The number of tubes of the multiwall nanotubes is not limited to three. In some embodiments, the multiwall nanotube has two coaxial nanotubes as shown in FIG. 2C, and in other embodiments, the multiwall nanotube includes the innermost tube 210 and the first to N-th nanotubes including the outermost tube 200N, where N is a natural number from 1 to about 30, as shown in FIG. 2D. In some embodiments, N ranges from 3 to 20, and 5 to 10 in other embodiments. In some embodiments, at least one of the first to the N-th outer layers is a nanotube coaxially surrounding the innermost nanotube 210. In some embodiments, all the innermost tube 210 and the first to the N-th outer layers are non-carbon-based nanotubes. In other embodiments, one or more of the tubes are carbon-based nanotubes.

In some embodiments, a diameter of the innermost nanotube is in a range from about 0.5 nm to about 20 nm, is in a range from about 1 nm to about 10 nm in other embodiments, and is in a range of about 2 nm to about 5 nm in other embodiments. In some embodiments, a diameter of the multiwall nanotubes (i.e., diameter of the outermost tube) is in a range from about 3 nm to about 40 nm and is in a range from about 5 nm to about 20 nm in other embodiments. In some embodiments, a length of the multiwall nanotube is in a range from about 0.5 μm to about 50 μm and is in a range from about 1.0 μm to about 20 μm in other embodiments.

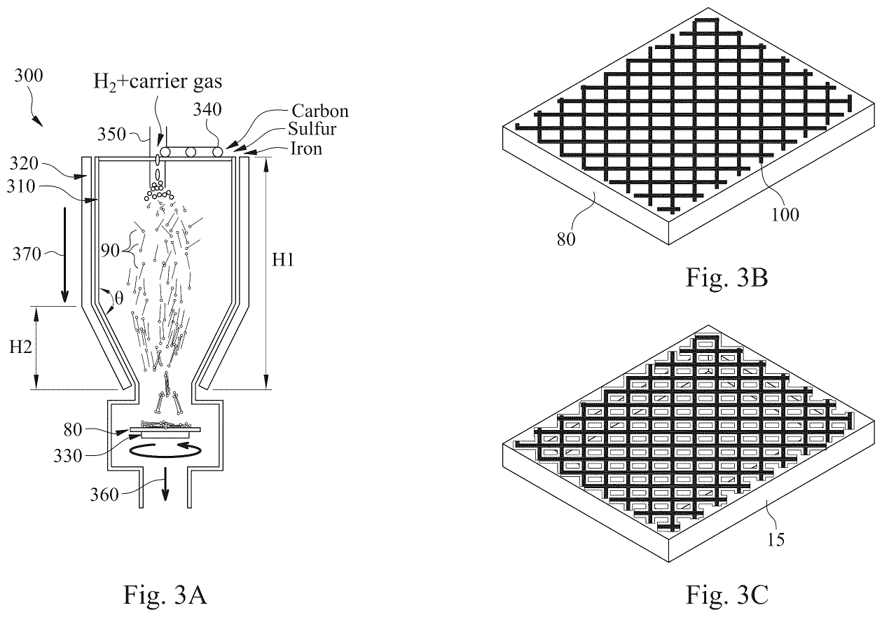

FIGS. 3A, 3B, and 3C show a manufacturing method of nanotube network membranes for a pellicle in accordance with embodiments of the present disclosure.

In some embodiments, carbon nanotubes (CNTs) 90 are formed by a chemical vapor deposition (CVD) process. In some embodiments, a CVD process is performed by using a vertical furnace as shown in FIG. 3A, and synthesized nanotubes are deposited on a support membrane 80 as shown in FIG. 3B. Then, the network membrane 100 formed over the support membrane 80 is detached from the support membrane 80, and transferred on to the pellicle frame 15 as shown in FIG. 3C.

In an embodiment illustrated in FIG. 3A, floating catalyst CVD process is used to form carbon nanotubes (CNTs). A funnel quartz design reactor 300 is used to form CNTs 90 in some embodiments. The reactor 300 includes tubular quartz walls 310. An upper portion of the quartz tube is cylindrical shape and a lower portion is cone shaped. The quartz tube walls are surrounded by a heater 320. The nanotubes 90 are deposited on a filter or support membrane 80. In some embodiments, a stage or mask 330, on which the support membrane 80 is disposed, rotates continuously or intermittently (step-by-step manner) so that the synthesized nanotubes are deposited on the support membrane 80 with different or random directions. In some embodiments, the support membrane is a filter paper. In some embodiments, the mask 330 is a plate that inhibits the CNTs from penetrating the support membrane 80. The CNTs can penetrate the filter in the unmasked regions of the support membrane 80 in some embodiments.

In some embodiments, the funnel quartz design reactor has a tube diameter ranging from about 1 cm to about 100 cm in the upper cylindrical portion tapering to a diameter of about 1 mm to about 10 cm at the end of the lower cone portion. The reactor has a height H1 ranging from about 200 cm to about 600 cm and the tapered portion of the lower cone portion has a height H2 ranging from about 10 cm to about 100 cm in some embodiments. A taper angle θ of the lower cone portion ranges from about 100° to about 150° in some embodiments.

To produce the CNTs 90, a carbon source is introduced into a reactor inlet 340 along with a catalyst. In some embodiments, a sulfur compound is also introduced into the reactor inlet 340. In some embodiments, the carbon source includes one or more hydrocarbon gases, including methane at a flow rate ranging from greater than 0 sccm to about 800 sccm, and ethane at a flow rate ranging from greater than 0 sccm to about 900 sccm. In some embodiments, the carbon source is introduced at a flow rate of about 4 sccm to about 200 sccm. In some embodiments, the catalyst may be any suitable catalyst, such as iron or an iron-containing catalyst, including ferrocene (Fe(C₅H₅)₂), and transition metal carbonyl complexes, including M(CO)ₓ where M is a transition metal, such as Cr, Mo, or W, and x ranges from 3 to 10 in some embodiments. Other suitable catalysts include: CoFe, Co, CoNi, Ni, CoMo, and FeMo. In some embodiments, the catalyst is introduced into the reactor at a flow rate ranging from greater than 0 sccm to about 1 sccm. In some embodiments, a sulfur containing compound is introduced into the reactor. The sulfur containing compound is one or more of hydrogen sulfide and thiophene. The sulfur containing compound is introduced into the reactor at a flow rate ranging from greater than 0 sccm to about 1 sccm. Hydrogen and a carrier gas are introduced into the reactor in a gas inlet 350. The carrier gas includes one or more of argon, nitrogen, and oxygen. The hydrogen is introduced into the reactor at a flow rate ranging from greater than 0 sccm to about 1000 sccm. The carrier gases may be introduced into the reactor at the following flow rates: argon—about 0 to about 50,000 sccm, nitrogen—about 0 sccm to about 60,000 sccm, and oxygen—about 0 to about 1 sccm.

The reactor is heated to a temperature of about 300 °C to about 1100 °C during the CNT growth operation in some embodiments. In some embodiments, a temperature gradient 370 is maintained along the height of the reactor. For example, in some embodiments, the temperature increases from the top of the reactor towards the bottom of the reactor or vice versa. In some embodiments, the temperature along the gradient increases from about 300 °C to about 1100 °C. The mask or stage 330 is rotated at a rate of about 0 rpm to about 500 rpm in some embodiments. A vacuum 360 is pulled during nanotube growth operation to provide a uniform CNT dispersion in some embodiments. In some embodiments, the growth operation is continued for a sufficient period of time to obtain a desired thickness of the nanotube network layer.

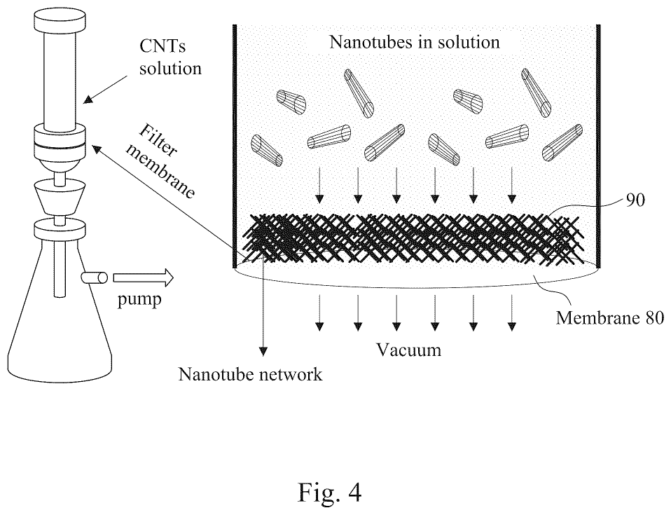

FIG. 4 shows another method of manufacturing a network membrane of nanotubes in accordance with an embodiment of the present disclosure. The nanotubes are formed by CVD methods in some embodiments, as previously explained. In some embodiments, the nanotubes are formed by various other methods, such as arc-discharge or laser ablation methods. The nanotubes are then dispersed in a solution. The solution includes a solvent, such as water or an organic solvent, and a surfactant, such as sodium dodecyl sulfate (SDS).

As shown in FIG. 4, a support membrane or filter 80 is placed between a chamber or a cylinder in which the nanotube dispersed solution is disposed and a vacuum chamber. In some embodiments, the support membrane is an organic or inorganic porous or mesh material. In some embodiments, the support membrane is a woven or non-woven fabric. In some embodiments, the support membrane has a circular shape in which a pellicle size of a 150 mm×150 mm square (the size of an EUV mask) can be placed.

As shown in FIG. 4, the pressure in the vacuum chamber is reduced so that a pressure is applied to the solvent in the chamber or cylinder. Since the mesh or pore size of the support membrane or filter is sufficiently smaller than the size of the nanotubes, the nanotubes 90 are captured by the support membrane while the solvent passes through the support membrane. The support membrane on which the nanotubes are deposited is detached from the filtration apparatus and dried. In some embodiments, the deposition by filtration is repeated to obtain a desired thickness of the nanotube network layer. In some embodiments, after the deposition of the nanotubes in the solution, other nanotubes are dispersed in the same or new solution and the filter-deposition is repeated. In other embodiments, after the nanotubes are dried, another filter-deposition is performed. In the repetition, the same type of nanotubes is used in some embodiments, and different types of nanotubes are used in other embodiments. In some embodiments, the nanotubes dispersed in the solution include multiwall nanotubes.

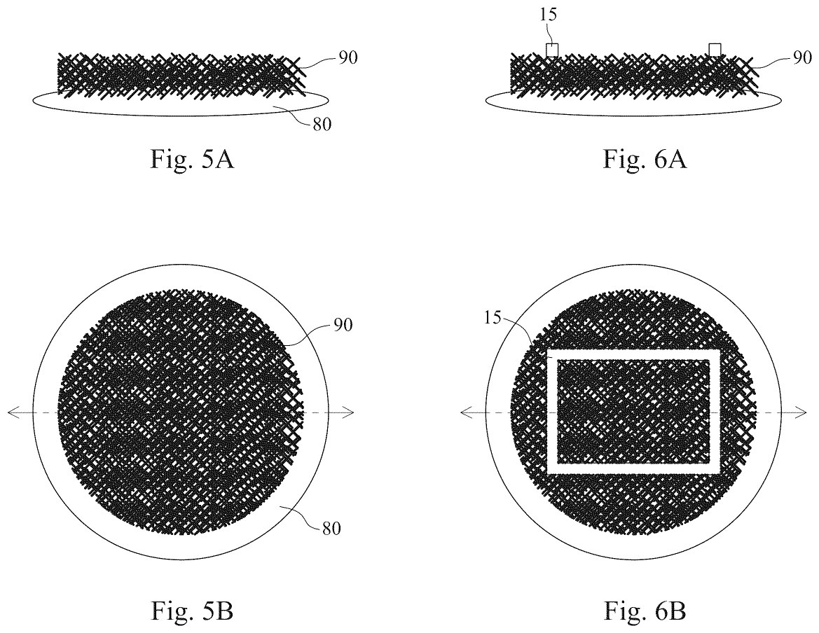

FIGS. 5A and 5B and 6A and 6B show cross sectional views (the “A” figures) and plan (top) views (the “B” figures) of the various stages for manufacturing a pellicle for an EUV photomask in accordance with an embodiment of the present disclosure. It is understood that additional operations can be provided before, during, and after the processes shown by FIGS. 5A-6B, and some of the operations described below can be replaced or eliminated, for additional embodiments of the method. The order of the operations/processes may be interchangeable. Materials, configurations, methods, processes and/or dimensions as explained with respect to the foregoing embodiments are applicable to the following embodiments, and the detailed description thereof may be omitted.

As shown in FIGS. 5A and 5B, a layer of CNTs 90 is formed on a support membrane 80 by one or more methods as explained above. In some embodiments, the layer of nanotubes 90 includes single wall nanotubes, multiwall nanotubes, or mixtures thereof. In some embodiments, the layer of carbon nanotubes 90 includes single wall nanotubes only.

Then, as shown in FIGS. 6A and 6B, a pellicle frame or border 15 is attached to the layer of carbon nanotubes 90. In some embodiments, the pellicle frame 15 is formed of one or more layers of a crystalline silicon, a polysilicon, a silicon oxide, a silicon nitride, an aluminum oxide, or a ceramic material. In some embodiments, as shown in FIG. 6B, the pellicle frame 15 has a rectangular (including square) frame shape, which is larger than the black border area of an EUV mask and smaller than the substrate of the EUV mask. In some embodiments, the pellicle frame is attached to the nanotube layer by a cold welding operation.

The layer of nanotubes 90 and the support membrane 80 are subsequently cut into a rectangular shape having the same size as or slightly larger than the pellicle frame 15, and then the support membrane 80 is detached or removed, in some embodiments. When the support membrane 80 is made of an organic material, the support membrane 80 is removed by wet etching using an organic solvent.

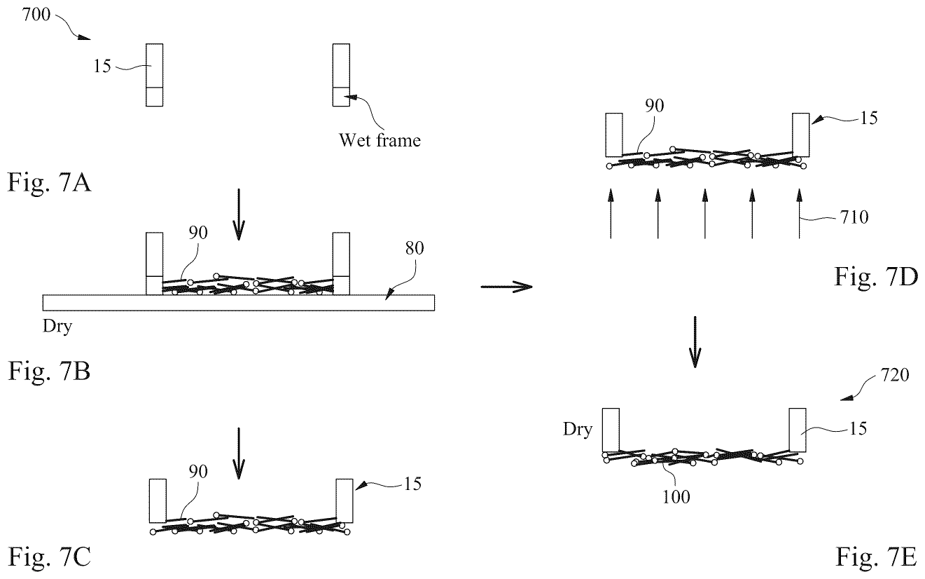

Sequential operations of a method 700 of manufacturing a pellicle according to some embodiments of the disclosure are shown in FIGS. 7A-7E. The frame 15 is initially wetted with an appropriate solvent, such as ethanol, to facilitate the attachment of the frame 15 to the nanotube layer 90, as shown in FIG. 7A. The frame 15 is contacted to the layer of nanotubes 90 and the structure is dried by air drying or vacuum drying, as shown in FIG. 7B, and then the support membrane is removed, as shown in FIG. 7C. The layer of nanotubes 90 is treated with an appropriate solvent vapor 710, such as ethanol vapor, in FIG. 7D to densify the nanotube layer. The solvent vapor facilitates bundling of the nanotubes in the nanotube layer. During the solvent vaporing, the CNTs contact and bond to each other thereby forming CNT bundles. The pellicle structure is subsequently dried by either air drying or vacuum drying in FIG. 7E to provide a pellicle structure 720 with a nanotube network membrane 100. In some embodiments, the solvent vaporing operation includes dipping the CNT membrane in a higher boiling point solvent, such as isoamyl acetate, and washing and drying the nanotube network membrane 100.

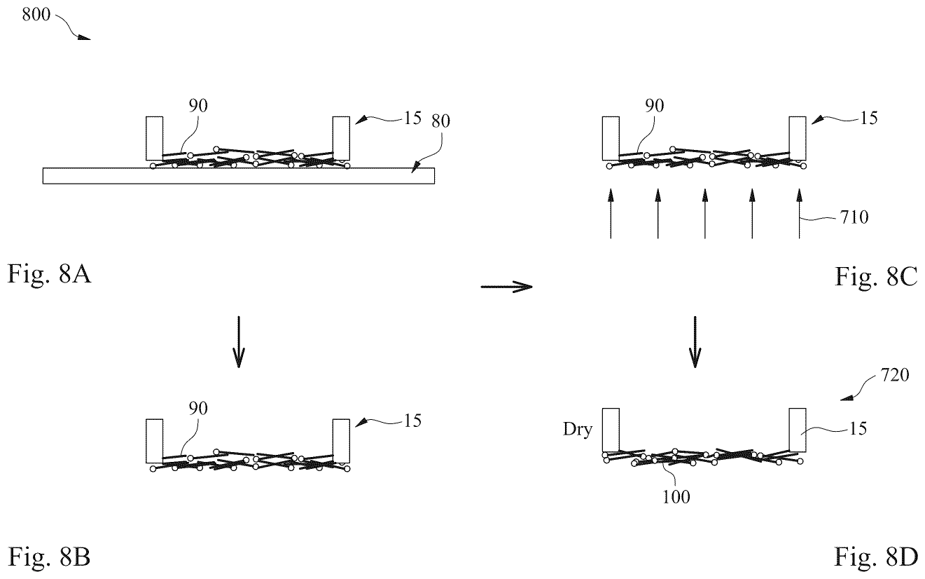

Sequential operations of another method 800 of manufacturing a pellicle according to some embodiments of the disclosure are shown in FIGS. 8A-8D. This method is similar to the method disclosed in FIGS. 7A-7E, with the exception that this method does not include the operation of wetting the frame 15 with the solvent. Thus, the operation illustrated in FIG. 8A corresponds to the operation illustrated in FIG. 7B, FIG. 8B corresponds to FIG. 7C, FIG. 8C corresponds to FIG. 7D, and the operation illustrated in FIG. 8D corresponds to FIG. 7E.

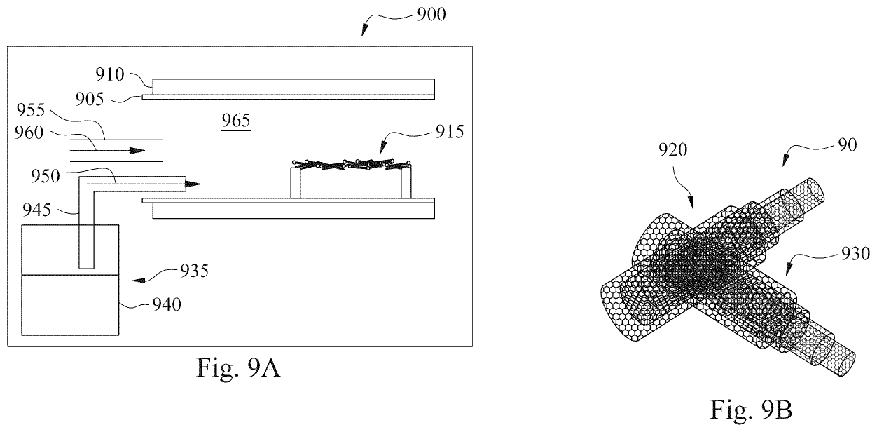

FIG. 9A shows a schematic view of a CVD apparatus 900 including a CVD reactor 965 for forming inorganic or ceramic layers wrapping the CNT nanotubes or CNT bundles to form an inorganic or ceramic wrapped membrane 915. In some embodiments, the CVD apparatus is a low pressure thermal CVD apparatus. In some embodiments, the CVD reactor includes quartz tube walls 905 and a heater 910 surrounding the quartz tube walls 905. The apparatus 900 may further include a source of the inorganic or ceramic layer material 935 including the inorganic or ceramic source material 940. When BNNTs are formed over the CNTs, H₃NBH₃ is used as the B and N precursors to deposit wrapping BN layers over the CNTs or CNT bundles in an embodiment. A stream of H₃NBH₃ 950 is introduced into the reactor through a conduit 945 from the source of the inorganic or ceramic layer material 935. In this embodiment, a mixture of 3-10 mol % H₂ in Ar 960 is introduced into the reactor at flow rate of about 300 sccm to be used as a carrier gas. Ar is also used as a purge gas in some embodiments. In some embodiments, the temperature in the reactor during the wrapping operation ranges from about 800 °C to about 1200 °C, and is in range from about 1000 °C to about 1100 °C in other embodiments. In some embodiments, the working pressure in the reactor is in a range from about 280 Pa to about 320 Pa, and is in a range from about 290 Pa to about 310 Pa in other embodiments. Due to the high temperature in the process of forming the inorganic or ceramic wrapping layers, the metal containing catalyst in the CNTs or CNT bundles are reduced or even removed, thereby improving EUV transmittance of the membrane.

In some embodiments, the boron nitride layer source material includes a mixture of H₃NBH₃ and h-BN powders at weight ratio ranging from about 1:5 to about 1:15. In some embodiments, the powder mixture is maintained at a temperature ranging from about 80 °C to about 100 °C before it is introduced into the CVD reactor.

In an example using H₃NBH₃ powder and 3 mol % H₂ in Ar at a flowrate of 300 sccm, the duration of the BN wrapping layer deposition is about 1 hour, at a working temperature of about 1000 °C to about 1100 °C, and a working pressure of about 300 Pa.

In another example using H₃NBH₃ powder and 3 mol % H₂ in Ar at a flowrate of 300 sccm, the duration of the BN wrapping layer deposition is about 3 hours, at a working temperature of about 1057 °C, and a working pressure of about 300 Pa.

In some embodiments, the inorganic or ceramic wrapped membrane 915 has a thickness ranging from about 5 nm to about 200 nm. In other embodiments, the membrane thickness ranges from about 10 nm to about 100 nm. In some embodiments, the CNTs are wrapped by about 2 to about 30 walls.

FIG. 9B illustrates CNTs 90 wrapped with one or more inorganic or ceramic layers 920 formed in the wrapping operation illustrated in FIG. 9A. In addition to boron nitride, other suitable inorganic or ceramic wrapping layers include any one or more of: SiC, MoS₂, MoSe₂, WS₂, WSe₂, SnS₂, SnS, ZrO₂, ZrO, and TiO₂.

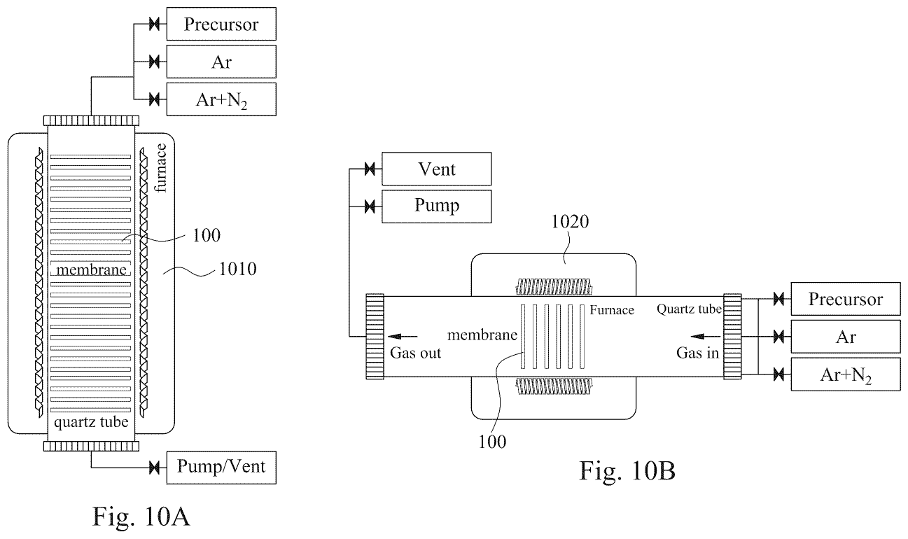

In some embodiments, the CVD reactor is a quartz tube furnace as illustrated in FIGS. 10A and 10B.

FIG. 10A shows forming the wrapping layers of the inorganic or ceramic layers over the CNTs or CNT bundles of the CNT network pellicle membranes 100 using a vertical furnace 1010 in accordance with some embodiments of the present disclosure, in which a plurality of the pellicle membranes 100 are horizontally arranged in the vertical furnace 1010. Thus, a plurality of CNT network pellicle membranes can be wrapped with the inorganic or ceramic layers simultaneously.

FIG. 10B shows forming the wrapping layers of the inorganic or ceramic layers over the CNTs or CNT bundles of the CNT network pellicle membranes 100 using a horizontal furnace 1020 in accordance with other embodiments of the present disclosure, in which a plurality of the pellicle membranes 100 are vertically arranged in the horizontal furnace 1020. Thus, a plurality of CNT network pellicle membranes can be wrapped with the inorganic or ceramic layers simultaneously.

In some embodiments, precursors for forming BNNTs include: B₂O₃, H₃BO₃, B₃H₆N₃, and BF₃, for the boron and NH₃/Ar, NH₃, and CO(NH₂)₂ for the nitrogen. In some embodiments H₃NBH₃ and a mixture of NaBH₄ and NH₄Cl are used as the precursors for both the boron and nitrogen in the boron nitride.

In some embodiments, H₃BO₃ is used as a B precursor, N₂ is used as an N precursor, Ar gas is used as a carrier gas, and Ar gas is also used as a purge gas to deposit the boron nitride wrapping layers 930. In some embodiments, the working temperature is in range from about 800 °C to about 1200 °C, and is in range from about 900 °C to about 1100 °C in other embodiments. In some embodiments, the working pressure is in range from about 0.8 atm to about 1.2 atm, and is in range from about 0.9 atm to about 1.1 atm in other embodiments.

In some embodiments, B₂O₃ is used as a B precursor, NH₃ is used as an N precursor, Ar gas is used as a carrier gas, with a ratio of NH₃ to Ar of 1:4, and Ar gas is used as a purge gas to deposit the BN wrapping layers 930. In some embodiments, the working temperature is in range from about 1000 °C to about 1400 °C, and is in range from about 1100 °C to about 1300 °C in other embodiments. In some embodiments, the working pressure is in range from about 0.8 atm to about 1.2 atm, and is in range from about 0.9 atm to about 1.1 atm in other embodiments. In an example, the duration of the BN wrapping layer deposition is about 1 hour, at a flow rate of the NH₃/Ar ranging from about 100 sccm to about 300 sccm, at a working temperature of about 1200 °C, and a working pressure of about 1 atm.

In another example, the B₂O₃ is first dissolved with the CNT and SDS for about 30 min at about 80 °C. Then the BN wrapping layer deposition is performed for about 4 hours, at an NH₃ flow rate of about 100 sccm, at a working temperature of about 1200 °C, and a working pressure of about 1 atm.

In another example, the B₂O₃ is first dissolved with ethanol at about 60 °C. Then the BN wrapping layer deposition is performed for about 3 min, at an NH₃ flow rate of about 30 sccm and an Ar flow rate of about 300 sccm, at a working temperature of about 900 °C, and a working pressure of about 10-3 Torr based on the Ar.

In some embodiments, H₃BO₃ is used as a B precursor, NH₃ is used as an N precursor at a flow rate of about 50 standard cubic centimeter per minute (sccm), and Ar gas is used as a purge gas to deposit wrapping layers 930. In some embodiments, the working temperature is in range from about 800 °C to about 1000 °C. In some embodiments, the working pressure is in range from about 0.9 atm to about 1.1 atm. In an example, the duration of the BN wrapping layer deposition is about 1 hour, at a flow rate of the NH₃ of about 50 sccm, at a working temperature of about 900 °C, and a working pressure of about 1 atm under an Ar ambient.

In another example using H₃BO₃ powder as the B precursor, the duration of the BN wrapping layer deposition is about 1 hour, using N₂ as the N precursor, at a working temperature of about 900 °C, and a working pressure of about 1 atm under an N₂ ambient.

In another example, the H₃BO₃ and CO(NH₂)₂ are first dissolved with CNTs and ethanol for about 1 hour at room temperature. Then the BN wrapping layer deposition is performed for about 3 hours, at a working temperature of about 900 °C, and a working pressure of about 1 atm under a N₂ ambient while flowing NH₃ at a flow rate of about 200 ml/min.

In another example, the H₃BO₃ and CO(NH₂)₂ are first dissolved with CNTs and ethanol for about 1 hour at room temperature. Then the BN wrapping layer deposition is performed for about 2 hours, at a working temperature of about 1000 °C, and a working pressure of about 1 atm under a N₂ ambient.

In some embodiments, NaBH₄ in powder form is sublimed and used as a B precursor, NH₄Cl is used as the N precursor, and Ar gas is used as a purge gas to form the wrapping layers 930. The BN wrapping layer deposition is performed for about 10 hours. In some embodiments, the working temperature is in range from about 400 °C to about 700 °C, and is in range from about 500 °C to about 600 °C in other embodiments. In some embodiments, the working pressure is in range from about 0.8 atm to about 1.2 atm, and is in range from about 0.9 atm to about 1.1 atm in other embodiments.

In another example, BF₃ is used as the B precursor and NH₃ is used as the N precursor. The BN wrapping layer deposition is performed for about 3 hours at a working temperature of about 1100 °C at a pressure of about 2.3 Torr.

In another example, B₃H₆N₃ liquid is used as the B precursor with Ar as a carrier gas at flowrate of about 5 sccm. The BN wrapping layer deposition is performed for about 30 min to about 2 hours at a working temperature of about 900 °C at a pressure of about 300 Pa.

In other embodiments, other source materials are used as precursors to deposit wrapping layers of other materials, such as SiC and transition metal dichalcogenides.

In some embodiments, SiC is formed or grown by CVD, using silane (SiH₄) and light hydrocarbons (C₂H₄ or C₃H₈) as precursors, diluted in a flow of hydrogen (H₂), at a growth temperature in a range from about 1500 °C to about 1600 °C and a pressure in a range from about 100 mbar to about 300 mbar.

In some embodiments, MoS₂ is formed or grown by CVD, using MoO₃ or MoCl₅ as a Mo precursor, in which solid MoO₃ or MoCl₅ in the form of powders are vaporized and converted to MoS₂ by reacting with S vapor at high temperatures (>800 °C). MoO₃ or MoCl₅ are placed at a zone having a temperature >800 °C in the furnace to vaporize them. Sulfur vapor as the S precursor is introduced into the furnace by heating sulfur powder and carrying the vapor with Ar flow. These precursors react to produce MoS₂.

In some embodiments, the inorganic or ceramic layers are formed at a temperature ranging from about 500 °C to about 1200 °C, a working pressure of about 10⁻³ Torr to about 760 Torr, for a wrapping layer deposition time of about 3 min to about 10 hours. In some embodiments the duration of the deposition of the wrapping layer ranges from about 1 hour to about 4 hours.

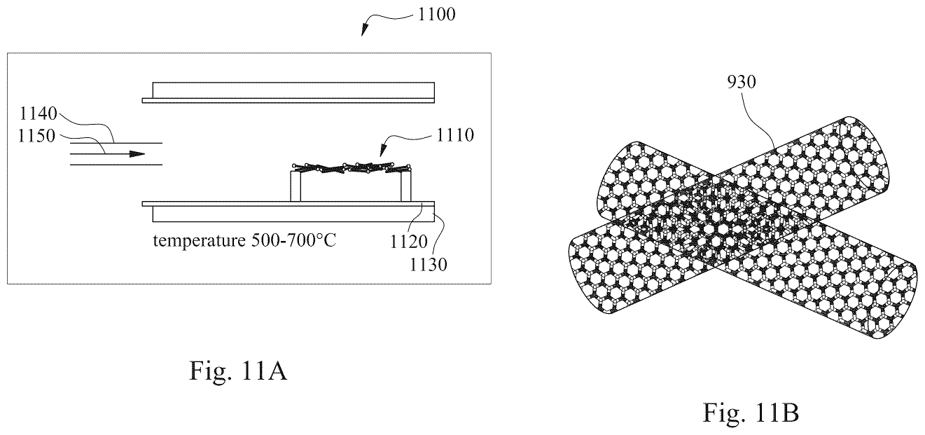

After forming the wrapping layers 930, the CNTs are at least partially removed. In some embodiments, the CNTs are removed by an oxidation operation. In some embodiments, the pellicle structures 1110 having the inorganic or ceramic wrapped CNTs are positioned in a furnace 1100, as shown in FIG. 11A. In some embodiments, the furnace is a quartz tube furnace having quartz walls 1120 surrounded by a heater 1130. The CNTs can be removed by passing air 1150 through an air inlet 1140 into the furnace and over the pellicle structures 1110. In some embodiments, the furnace is heated to temperature ranging from about 500 °C to about 700 °C for about 1 hour to about 3 hours while air is passed through the furnace at a flow rate ranging from about 1 L/min to about 10 L/min. In other embodiments, the air flow rate ranges from about 1.8 L/min to about 5 L/min. While air can be used to oxidize the CNTs, in some embodiments, oxygen used for the oxidation is mixed with another carrier gas, such as argon. The inorganic or ceramic wrapping layers do not react with the oxygen, and thus they are not oxidized during the CNT removal operation. The CNTs, on the other hand, react with the oxygen and form carbon dioxide, which is carried away by the carrier gas. In some embodiments, the CNTs are completely removed from the pellicle structure. FIG. 11B shows a portion of the pellicle network membrane formed of nanotubes 930 where the CNTs are completely removed according to some embodiments of the disclosure.

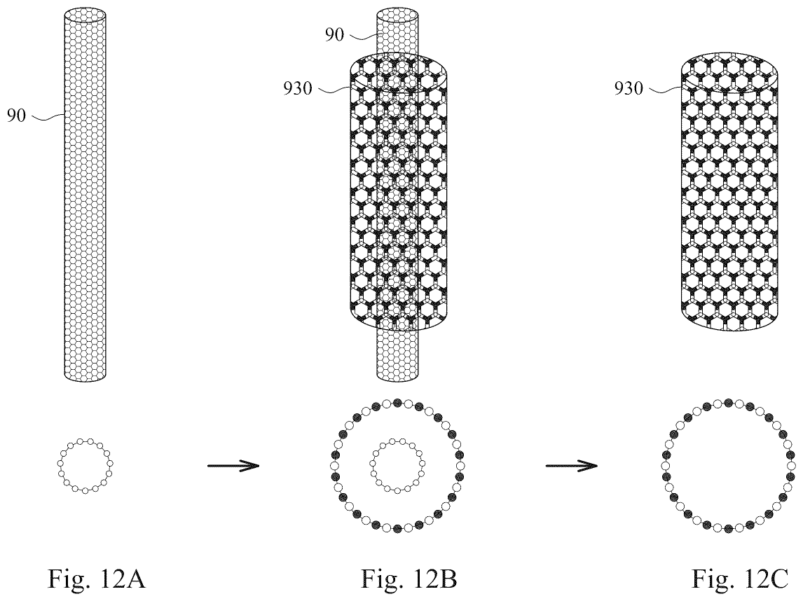

FIGS. 12A, 12B, and 12C show three dimensional and cross-sectional views of nanotube structures produced by manufacturing processes according to embodiments of the disclosure. FIG. 12A illustrates a CNT 90 formed according to an embodiment of the disclosure. FIG. 12B illustrates forming the inorganic or ceramic nanotube 930 around the CNT 90, and FIG. 12C illustrates the nanotube 930 following removal of the CNT, according to embodiments of the disclosure.

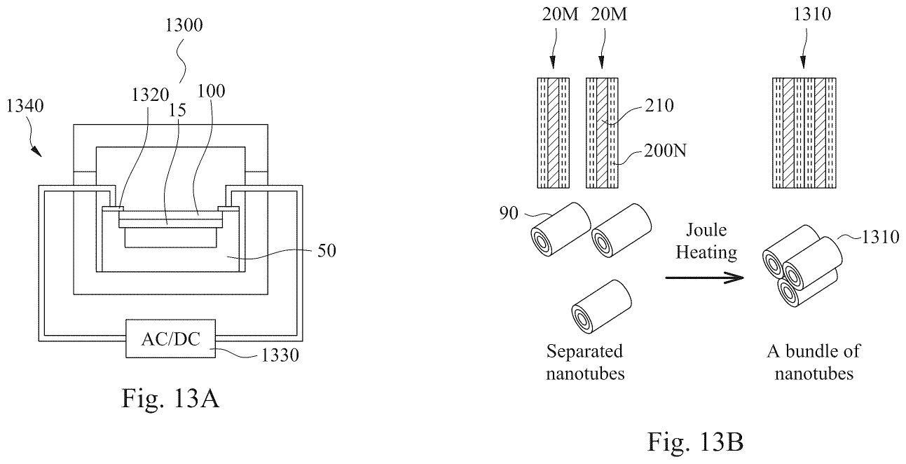

In some embodiments, bonded bundles 1310 of CNTs are formed by Joule heating, as shown in FIGS. 13A and 13B. As shown in FIG. 13A, a pellicle 10 including a membrane 100 and a frame 15 (as shown in FIGS. 1A and 1B) is placed over an insulating support 50 and is clamped at the edge portions of the pellicle by parts of the insulating support 50 and electrodes 1320 disposed over the pellicle 10. The insulating support 50 is made of ceramic in some embodiments, and the electrodes 1320 are made of metal, such as tungsten, copper, or steel. The electrodes 1320 are attached to contact the membrane 100. In some embodiments, the electrodes 1320 are attached to two side portions (e.g., left and right) of the membrane 100. In some embodiments, the electrodes 1320 are connected to a current source (power supply) 1330 by wires.

As shown in FIG. 13A, a Joule heating apparatus 1300 on which a membrane 100 formed of one or more nanotube materials is mounted is placed in a vacuum chamber 1340. In some embodiments, the vacuum chamber 1340 includes a bottom part in which the Joule heating apparatus is placed and an upper (lid) part, and a gasket (e.g., O-ring) is disposed between the bottom part and the upper part. The wires of the Joule heating apparatus are connected to outside wires, which are connected to the power supply 1330.

In the Joule heating operation, the vacuum chamber is evacuated to a pressure equal to or lower than 10 Pa in some embodiments. In some embodiments, the pressure is more than 0.1 Pa. The power supply 1330 applies current to the membrane 100 so that the current passes through the membrane generating heat. In some embodiments, the current is DC, and in other embodiments, the current is AC or pulse current.

In some embodiments, the current from the power supply 1330 is adjusted such that the membrane is heated at a temperature in a range from about 800 °C to 2000 °C. In some embodiments, the lower limit of the temperature is about 1000 °C, 1200 °C or 1500 °C, and the upper limit is about 1500 °C, 1600 °C or 1800 °C to cause separated nanotubes to bond to each other and form a bundle.

In some embodiments, the pellicle frame 15 is made of ceramic or a metal or metallic material having a higher electric resistance than the carbon nanotube membrane 100.

In some embodiments, the Joule heating treatment is performed in an inert ambient gas, such as N₂ and/or Ar. In some embodiments, the Joule heating treatment is performed for about five seconds to about 60 minutes, and is performed to about 30 seconds to about 15 minutes in other embodiments.

As shown in FIG. 13B, in some embodiments, the Joule heating operation causes single separated nanotubes 90 (single-wall or multiwall nanotubes) to join and form a bundle 1310 of nanotubes having a seamless graphitic structure, in which the nanotubes are firmly bonded or joined more than merely contacting each other. Two or more nanotubes 90 can be connected (bonded or joined) to form a bundle 1310 of nanotubes. In some embodiments, 2-15 nanotubes are bonded to form a medium bundle. In some embodiments, 16-100 nanotubes are bonded to form a large bundle. In some embodiments, more than 100 nanotubes are bonded to form a very large bundle.

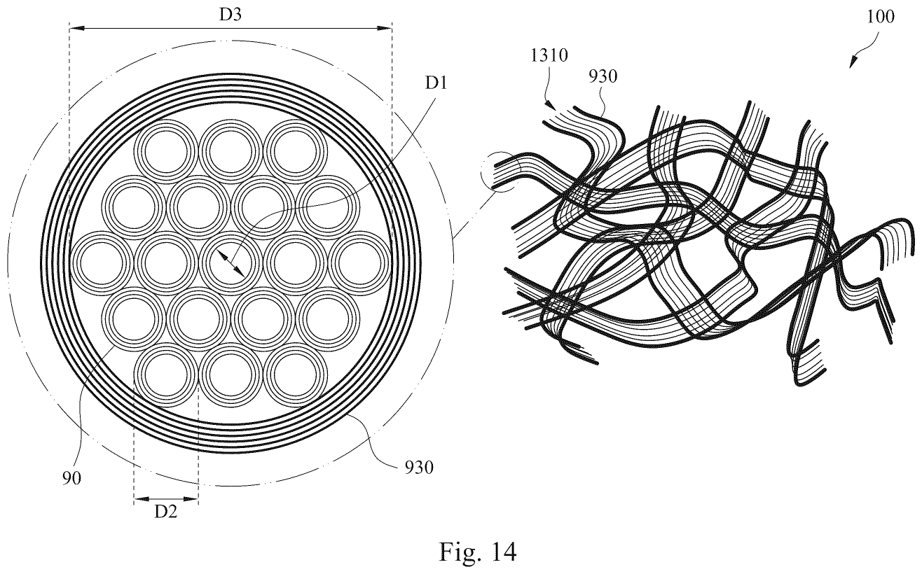

FIGS. 14, 15, 16, and 17 show structures of various membranes 100 of a pellicle for an EUV photomask in accordance with embodiments of the present disclosure. The pellicle includes a frame 15 and a membrane 100 attached to the frame 15 as shown in FIG. 1A or FIG. 1B. FIGS. 14-17 show a portion of the pellicle membrane 100 and a detailed cross-sectional view of one of the multiwall nanotubes of the pellicle membrane.

As shown in FIG. 14, in some embodiments, the membrane 100 includes a plurality of nanotube bundles 1310, each nanotube bundle 1310 including a plurality of single wall or multiwall CNTs 90 bonded together. The plurality of bonded CNTs 90 are coaxially arranged. The membrane 100 further includes a wrapping layer 930 made of a plurality of coaxial walls made of a different material than the CNTs, surrounding each of the plurality of nanotube bundles 1310.

In some embodiments, as shown in FIG. 14, the inner diameter D1 of the plurality of multiwall carbon nanotubes (MWCNTs) 90 is equal to or less than 2 nm (D1≤2 nm). In some embodiments, each nanotube 90 has an outer diameter D2 of about 2 nm to about 20 nm, depending on the number of walls. In some embodiments, each CNT 90 includes 1 to about 20 walls. In some embodiments, each CNT 90 includes about 3 to about 15 walls. In some embodiments each CNT 90 includes about 4 to about 10 walls. In some embodiments, the outer diameter of each CNT 90 ranges from about 2 nm to about 20 nm. In some embodiments, the outer diameter of each CNT 90 ranges from about 4 nm to about 10 nm. In some embodiments, the plurality of nanotubes 90 do not include any layers made of a different material. In other words, each of the plurality of nanotubes 90 is made of the same material.

In some embodiments, the inner diameter D3 of the wrapping layer 930 ranges from about 10 nm to about 100 nm depending on the size of the CNT bundle 1310. In some embodiments, the inner diameter D3 of the wrapping layer 930 ranges from about 20 nm to about 50 nm. In some embodiments, the wrapping layer 930 surrounds about 3 to about 100 CNTs 90. In some embodiments, the wrapping layer 930 surrounds about 10 to about 50 CNTs 90. In some embodiments, the wrapping layer 930 surrounds about 15 to about 40 CNTs 90. In some embodiments, the wrapping layer 930 surrounds over 100 CNTs 90. In some embodiments, the wrapping layer 930 includes 1 to about 20 walls. In some embodiments, the wrapping layer 930 includes about 3 to about 15 walls. In some embodiments, the wrapping layer 930 includes about 4 to about 10 walls. In an example, the wrapping layer 930 includes 4 walls; has an inner diameter D3 of about 20 nm; and surrounds 19 MWCNTs 90, wherein the MWCNTs 90 each have four walls, an inner diameter of less than or equal to 2 nm, and an outer diameter of about 4.2 nm.

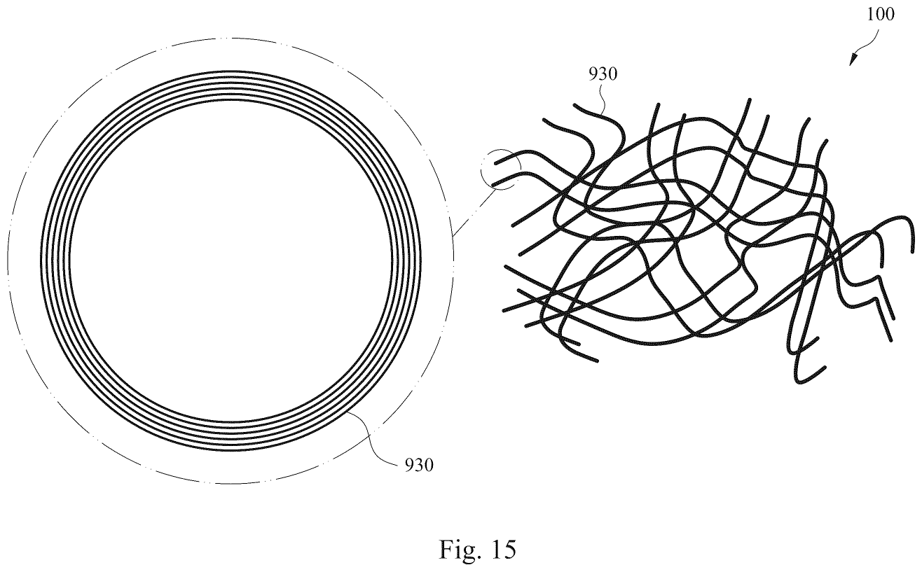

As shown in FIG. 15, in some embodiments, the membrane 100 includes a plurality of nanotubes made of the wrapping layer 930. In some embodiments, the CNTs 90 in the membrane structure of FIG. 14 are removed by an oxidation operation, as described herein. Although FIG. 15 illustrates an embodiment where the CNTs are completely removed, in some embodiments, the CNTs are only partially removed by the oxidation operation.

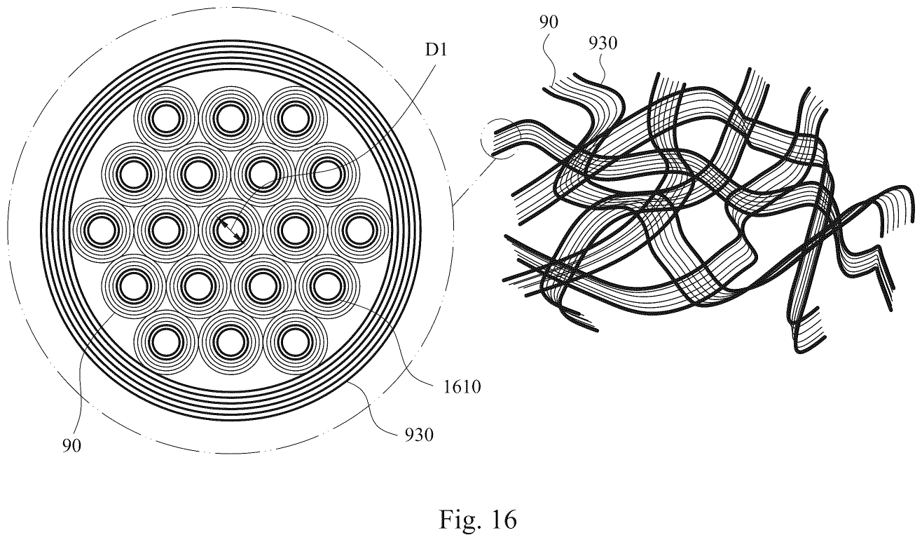

In other embodiments, as shown in FIG. 16, when the inner (or innermost) diameter D1 of the CNTs 90 is greater than 2 nm (D1>2 nm), the plurality of CNTs 90 further includes one or more walls 1610 of the inorganic or ceramic material filled within the innermost walls of the CNTs 90. In some embodiments, the number of walls 1610 filling the inner diameters of the CNTs 90 ranges from 1 to about 4 walls. In some embodiments, filling the innermost diameter D1 of the CNTs 90 with the inorganic or ceramic material is dependent on the working temperature of the wrapping operation. In some embodiments, a greater amount of the inorganic or ceramic material is filled within the innermost walls of the CNTs 90 at higher working temperatures.

As shown in FIGS. 14 and 16, in some embodiments, the first material used to form the nanotubes 90 includes a carbon-based nanotube material, and the different second material used to form the coaxial wrapping layers 930 and coaxial inner walls 1610 filling the inner-most walls of the CNTs includes one or more selected from BN, h-BN, SiC, MoS₂, MoSe₂, WS₂, WSe₂, SnS₂, SnS, ZrO₂, ZrO or TiO₂. In some embodiments, two adjacent walls of the wrapping layer 930 or the coaxial inner walls 1610 are made of different materials.

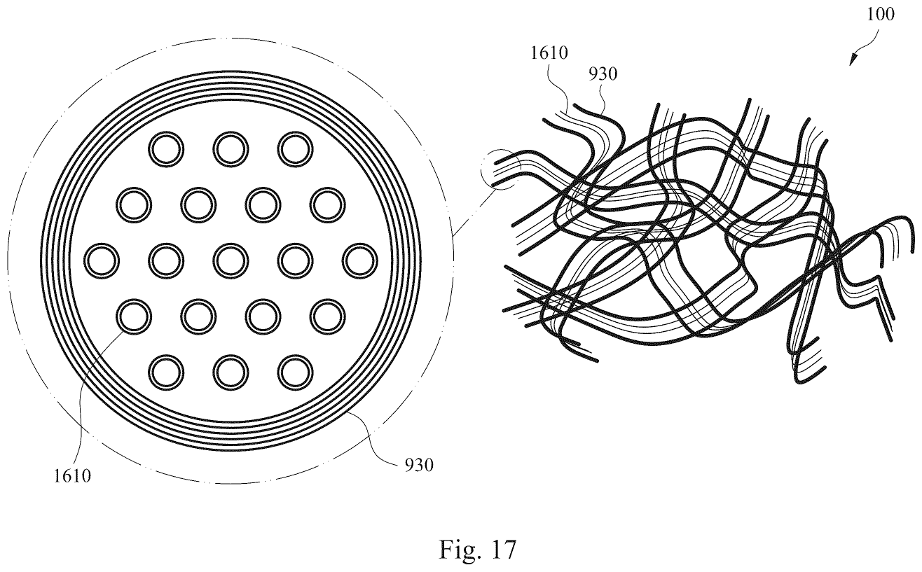

In some embodiments, the CNTs 90 of the membrane structure of FIG. 16 are removed by an oxidation operation disclosed herein to provide the membrane structure 100 of FIG. 17. As shown in FIG. 17, the pellicle membrane structure 100 includes a plurality of inorganic or ceramic nanotubes 1610 surrounded by the inorganic or ceramic wrapping layer 930 in some embodiments. Although the CNTs are completely removed in the structure illustrated in FIG. 17, in some embodiments, the CNTs are only partially removed by the oxidation operation.

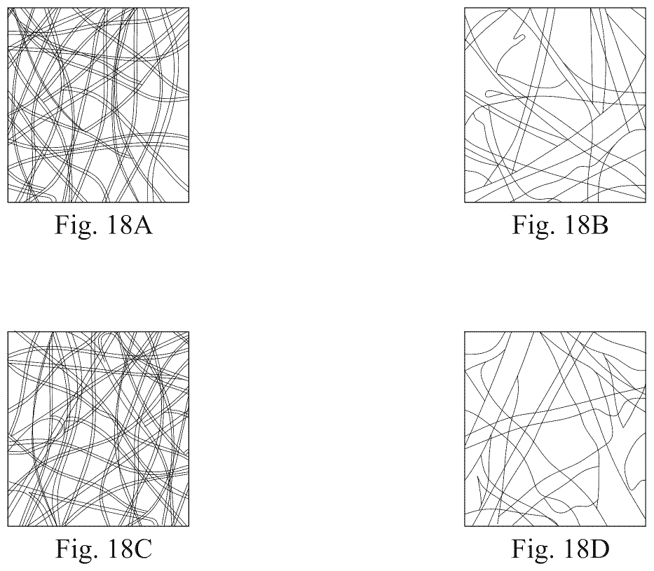

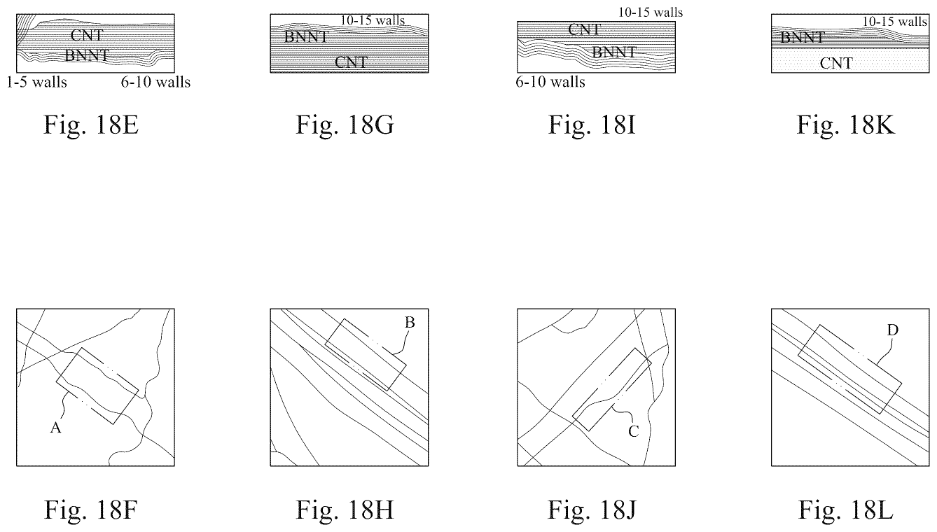

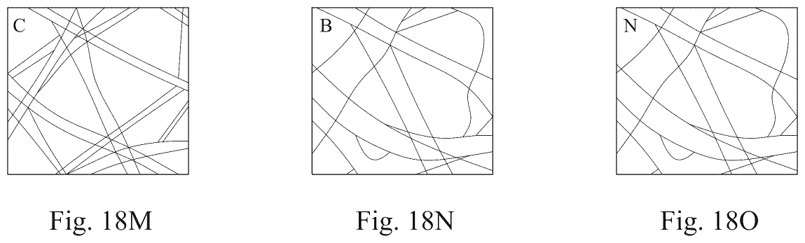

FIGS. 18A, 18B, 18C, and 18D are illustrations of transmission electron microscopy (TEM) images of BNNT membrane structures according to embodiments of the present disclosure. FIGS. 18E-18L are detailed illustrations of TEM images of BNNT wrapped CNT membrane structures according to embodiments of the present disclosure. FIGS. 18F, 18H, 18J, and 18L are detailed views of various regions of the BNNT wrapped CNT membrane structures. FIG. 18E is a cross-sectional detail of region A in FIG. 18F. FIG. 18G is a cross-sectional detail of region B in FIG. 18H. FIG. 18I is a cross-sectional detail of region C in FIG. 18J. FIG. 18K is a cross-sectional detail of region D in FIG. 18L. As shown in FIGS. 18E, 18G, 18I, and 18K the multiwall (MW) BNNT wraps around the MWCNT. The number of walls of the MWBNNTs varies along the length of the MWCNTs in some embodiments.

FIGS. 18M, 18N, and 18O are detailed illustrations of TEM images of the same region of a BNNT wrapped CNT membrane structure. FIG. 18M illustrates the carbon distribution in the TEM image, FIG. 18N illustrates the boron distribution, and FIG. 18O illustrates the nitrogen distribution.

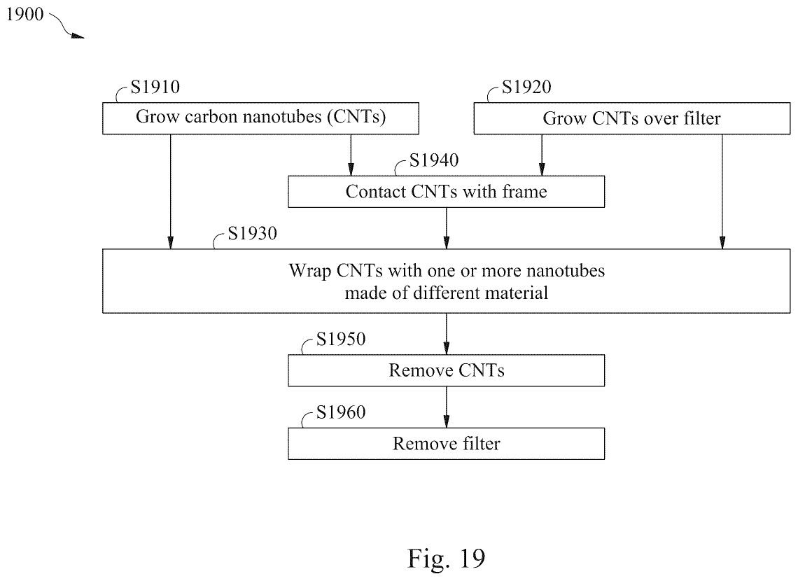

FIGS. 19-21 are flowcharts showing methods of manufacturing a pellicle according to embodiments of the present disclosure. It is understood that additional operations can be provided before, during, and after the processes shown in FIGS. 19-21 and some of the operations described below can be replaced or eliminated, for additional embodiments of the method. The order of the operations/processes may be interchangeable.

A method 1900 of manufacturing a pellicle according to embodiments of the disclosure is shown in the flowchart of FIG. 19. In operation S1910 carbon nanotubes (CNTs) 90 are grown. In some embodiments, the CNTs 90 are grown over a filter 80 in operation S1920. The CNTs 90 are wrapped with one or more nanotubes 930 made of a different material in operation S1930. In some embodiments, a frame 15 is contacted with the CNTs in operation S1940. The CNTs are removed in operation S1950. In some embodiments the filter is removed in operation S1960. In some embodiment, the different material includes one or more of boron nitride, hexagonal boron nitride (h-BN), SiC, MoS₂, MoSe₂, WS₂, WSe₂, SnS₂, SnS, ZrO₂, ZrO, and TiO₂. In some embodiments, the CNTs are removed by oxidizing the CNTs in operation S1950. In some embodiments, oxidizing the CNTs includes heating the CNTs at a temperature ranging from 500 °C to 700 °C in operation S1950.

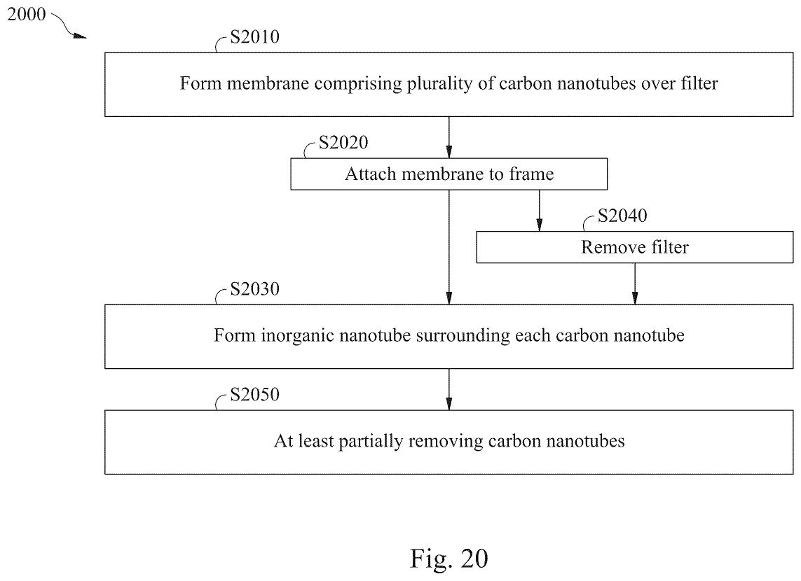

Another method 2000 of manufacturing a pellicle according to embodiments of the disclosure is shown in the flowchart of FIG. 20. A membrane 100 including a plurality of carbon nanotubes 90 is formed over a filter 80 in operation S2010. The membrane 100 is attached to a frame 15 in operation S2020. An inorganic nanotube 930 is formed surrounding each of the carbon nanotubes 90 in operation S2030. The inorganic nanotubes 930 are made of a different material than the carbon nanotubes 90. In some embodiments, the filter 80 is removed after attaching the membrane to the frame 15 in operation S2040. The carbon nanotubes are at least partially removed in operation S2050. In some embodiments, the carbon nanotubes 90 are at least partially removed by oxidizing the carbon nanotubes 90 in operation S2050. In some embodiments, oxidizing the carbon nanotubes 90 includes heating the carbon nanotubes 90 at a temperature ranging from 500 °C to 700 °C in operation S2050. In some embodiments, the carbon nanotubes are completely removed in operation S2050. In some embodiments, the different material includes one or more of boron nitride, hexagonal boron nitride (h-BN), SiC, MoS₂, MoSe₂, WS₂, WSe₂, SnS₂, SnS, ZrO₂, ZrO, and TiO₂. In some embodiments, forming the inorganic nanotube 930 in operation S2030 includes forming a multiwall inorganic nanotube 930 surrounding each of the carbon nanotubes 90. In some embodiments, the plurality of carbon nanotubes include multiwall carbon nanotubes 90.

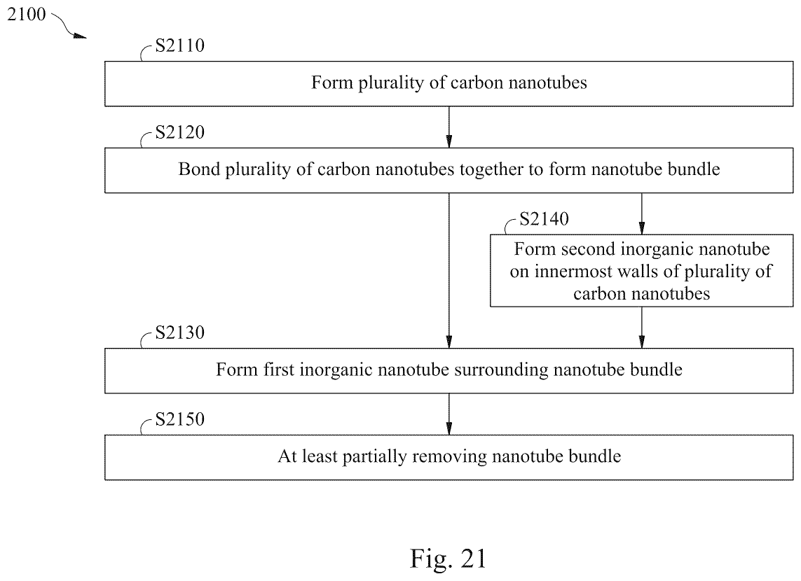

Another method 2100 of manufacturing a pellicle according to embodiments of the disclosure is shown in the flowchart of FIG. 21. A plurality of carbon nanotubes 90 is formed in operation S2110. Each of the carbon nanotubes 90 includes one or more walls. The plurality of carbon nanotubes 90 are bonded together to form a nanotube bundle 1310 in operation S2120. A first inorganic nanotube 930 is formed surrounding the nanotube bundle 1310 in operation S2130. The first inorganic nanotube 930 is made of a different material than the carbon nanotubes 90. In some embodiments, second inorganic nanotubes 1610 are formed on innermost walls of the plurality of nanotubes 90 before forming the first inorganic nanotube in operation S2140. The second inorganic nanotubes 1610 are made of a different material than the carbon nanotubes 90. The nanotube bundle is at least partially removed in operation S2150. In some embodiments, the second inorganic nanotubes 1610 include a plurality of coaxial walls. In some embodiments, the first inorganic nanotube 930 includes a plurality of coaxial walls. In some embodiments, the nanotube bundle is completely removed in operation S2150.

Properties of BNNTs compared to CNTs are shown in Table 1.

TABLE 1

| | Boron Nitride Nanotubes | | Carbon Nanotubes | |
|---|---|---|---|---|
| | (BNNTs) | | (CNTs) | |
| Appearance | White | | Black | |
| Electrical | Insulating, wide band gap | | Metallic or | |
| Conductivity | (5-6 eV) | | Semiconducting | |
| | | | (0.5-2 eV) | |
| Young's Modulus | 1.2 | Tpa | 1.09-1.25 | Tpa |
| Thermal | 350 ± 20 | Wm⁻¹K⁻¹ | 300 ± 20 | Wm⁻¹K⁻¹ |
| Conductivity | | | | |

| Thermal Stability | Stable up to 800-900 °C | Stable up to 500-700 °C |
|---|---|---|
| Optical Properties | Visible and IR transparent, | Full spectrum absorption |
| | some regions of UV | |
| | absorption | |

As shown in Table 1, BNNTs have higher thermal conductivity and higher thermal stability than CNTs.

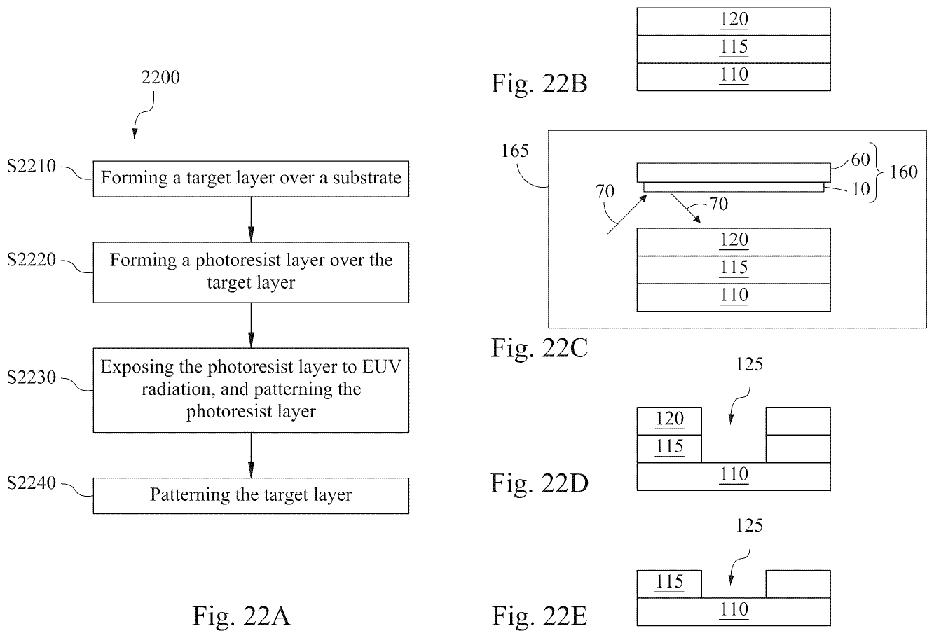

FIG. 22A shows a flowchart of a method 2200 of making a semiconductor device, and FIGS. 22B, 22C, 22D, and 22E show a sequential manufacturing method of making a semiconductor device in accordance with embodiments of present disclosure. A semiconductor substrate or other suitable substrate to be patterned to form an integrated circuit thereon is provided. In some embodiments, the semiconductor substrate includes silicon. Alternatively or additionally, the semiconductor substrate includes germanium, silicon germanium or other suitable semiconductor material, such as a Group III-V semiconductor material. At S2210, of FIG. 22A, a target layer 115 to be patterned is formed over the semiconductor substrate 110. In certain embodiments, the target layer 115 is the semiconductor substrate. In some embodiments, the target layer 115 includes a conductive layer, such as a metallic layer or a polysilicon layer; a dielectric layer, such as silicon oxide, silicon nitride, SiON, SiOC, SiOCN, SiCN, hafnium oxide, or aluminum oxide; or a semiconductor layer, such as an epitaxially formed semiconductor layer. In some embodiments, the target layer 115 is formed over an underlying structure, such as isolation structures, transistors or wirings. At S2220, a photoresist layer 120 is formed over the target layer, as shown in FIG. 22B. The photoresist layer 120 is sensitive to the radiation 70 from the exposure radiation source during a subsequent photolithography exposing operation. In the present embodiment, the photoresist layer 120 is sensitive to EUV light used in the photolithography exposing operation. The photoresist layer 120 may be formed over the target layer 115 by spin-on coating or other suitable technique. The coated photoresist layer may be further baked to drive out solvent in the photoresist layer. At S2230, the photoresist layer 120 is patterned in a photolithography exposure apparatus 165 using the pellicle/photomask structure 160, as set forth above, as shown in FIG. 22C. During the photolithography exposing operation, an integrated circuit (IC) design pattern defined on the photomask 60 is imaged to the photoresist layer 120 to form a latent pattern thereon. The patterning of the photoresist layer further includes developing the exposed photoresist layer to form a patterned photoresist layer having one or more openings 125. In one embodiment where the photoresist layer is a positive tone photoresist layer, the exposed portions of the photoresist layer are removed during the developing operation. The patterning of the photoresist layer may further include other operations, such as various baking operations at different stages. For example, a post-exposure-baking (PEB) process may be implemented after the photolithography exposure operation and before the developing operation.

At S2240, the target layer 115 is patterned using the patterned photoresist layer 120 as an etching mask, as shown in FIG. 22D. In some embodiments, the patterning the target layer includes etching the target layer using the patterned photoresist layer as an etch mask. The portions of the target layer exposed within the openings of the patterned photoresist layer are etched while the remaining portions are protected from etching. Further, the patterned photoresist layer may be removed by wet stripping or plasma ashing, as shown in FIG. 22E.

Other embodiments include other operations before, during, or after the operations described above. In some embodiments, the disclosed methods include forming fin field effect transistor (FinFET) structures. In some embodiments, a plurality of active fins are formed on the semiconductor substrate. Such embodiments, further include etching the substrate through the openings of a patterned hard mask to form trenches in the substrate; filling the trenches with a dielectric material; performing a chemical mechanical polishing (CMP) process to form shallow trench isolation (STI) features; and epitaxy growing or recessing the STI features to form fin-like active regions. In some embodiments, one or more gate electrodes are formed on the substrate. Some embodiments include forming gate spacers, doped source/drain regions, contacts for gate/source/drain features, etc. In other embodiments, a target pattern is formed as metal lines in a multilayer interconnection structure. For example, the metal lines may be formed in an inter-layer dielectric (ILD) layer of the substrate, which has been etched to form a plurality of trenches. The trenches may be filled with a conductive material, such as a metal; and the conductive material may be polished using a process such as chemical mechanical planarization (CMP) to expose the patterned ILD layer, thereby forming the metal lines in the ILD layer. The above are non-limiting examples of devices/structures that can be made and/or improved using the method described herein.

In some embodiments, active components such diodes, field-effect transistors (FETs), metal-oxide semiconductor field effect transistors (MOSFET), complementary metal-oxide semiconductor (CMOS) transistors, bipolar transistors, high voltage transistors, high frequency transistors, sheet FETs, FinFETs, gate all around FETs (GAA FETs), other three-dimensional (3D) FETs, other memory cells, and combinations thereof are formed, according to embodiments of the disclosure.

Removal of the CNTs reduces EUV radiation absorption by the pellicle membrane. The remaining wrapping layer nanotube structure provides improved mechanical properties over CNTs. Embodiments of the present disclosure provide nanotube network membranes having excellent EUV radiation transmission at 13.5 nm and 6.7 nm wavelengths. Embodiments of the present disclosure provide nanotube network membranes having EUV radiation transmission of up to 99% at these wavelengths, which exceeds the up to 96.5% EUV transmission of CNT based membranes. The high temperature operation of forming the inorganic or ceramic wrapping layers also removes residual metal catalysts used in forming the CNTs, thereby further improving the EUV radiation transmission. Embodiments of the present disclosure provide high transmittance and high strength EUV pellicles, thereby improving the manufacturing efficiency of semiconductor devices.

An embodiment of the disclosure includes a method of forming a pellicle, including growing carbon nanotubes (CNTs), wrapping the CNTs with one or more nanotubes made of a different material, and removing the CNTs. In an embodiment, the method includes growing the CNTs over a filter. In an embodiment, the method includes removing the filter. In an embodiment, the method includes contacting the CNTs with a frame. In an embodiment, the different material includes one or more of boron nitride, hexagonal boron nitride (h-BN), SiC, MoS₂, MoSe₂, WS₂, WSe₂, SnS₂, SnS, ZrO₂, ZrO, and TiO₂. In an embodiment, the CNTs are removed by oxidizing the CNTs. In an embodiment, oxidizing the CNTs includes heating the CNTs at a temperature ranging from 500 °C to 700 °C. In an embodiment, the CNTs include multiwall carbon nanotubes.

Another embodiment of the disclosure includes a method of manufacturing a pellicle including forming a membrane including a plurality of carbon nanotubes over a filter. The membrane is attached to a frame. An inorganic nanotube is formed surrounding each of the carbon nanotubes. The inorganic nanotubes are made of a different material than the carbon nanotubes. The carbon nanotubes are at least partially removed. In an embodiment, the method includes removing the filter after attaching the membrane to the frame. In an embodiment, the different material includes one or more of boron nitride, hexagonal boron nitride (h-BN), SiC, MoS₂, MoSe₂, WS₂, WSe₂, SnS₂, SnS, ZrO₂, ZrO, and TiO₂. In an embodiment, the carbon nanotubes are at least partially removed by oxidizing the carbon nanotubes. In an embodiment, oxidizing the carbon nanotubes includes heating the carbon nanotubes at a temperature ranging from 500 °C to 700 °C. In an embodiment, the carbon nanotubes are completely removed. In an embodiment, forming the inorganic nanotube includes forming a multiwall inorganic nanotube surrounding each of the carbon nanotubes.

Another embodiment of the disclosure includes a method of manufacturing a pellicle including forming a plurality of carbon nanotubes. Each of the carbon nanotubes includes one or more walls. The plurality of carbon nanotubes are bonded together to form a nanotube bundle. A first inorganic nanotube is formed surrounding the nanotube bundle. The first inorganic nanotube is made of a different material than the carbon nanotubes. The nanotube bundle is at least partially removed. In an embodiment, the method includes forming a second inorganic nanotube on innermost walls of the plurality of nanotubes, wherein the second inorganic nanotubes are made of a different material than the carbon nanotubes. In an embodiment, the second inorganic nanotubes include a plurality of coaxial walls. In an embodiment, the first inorganic nanotube includes a plurality of coaxial walls. In an embodiment, the nanotube bundle is completely removed. Another embodiment of the disclosure includes a pellicle including a membrane including a plurality of inorganic nanotubes. The membrane does not include carbon nanotubes. A frame is disposed over the membrane. In an embodiment, the inorganic nanotubes include one or more of boron nitride, hexagonal boron nitride (h-BN), SiC, MoS₂, MoSe₂, WS₂, WSe₂, SnS₂, SnS, ZrO₂, ZrO, and TiO₂. In an embodiment, each inorganic nanotube includes a plurality of coaxial walls. In an embodiment, each inorganic nanotube includes 3 to 30 coaxial walls. In an embodiment, at least one coaxial wall of the plurality of coaxial walls is formed of a different material than another coaxial wall of the plurality of coaxial walls. In an embodiment, the membrane has a thickness ranging from 10 to 100 nm. In an embodiment, the inorganic nanotubes have an interior diameter ranging from 0.5 nm to 10 nm.

Another embodiment of the disclosure includes a pellicle including a membrane including a plurality of inorganic nanotube bundles. Each of the plurality of inorganic nanotube bundles includes a plurality of first inorganic nanotubes surrounded by a second inorganic nanotube. The first and second inorganic nanotubes independently include one or more of boron nitride, hexagonal boron nitride (h-BN), SiC, MoS₂, MoSe₂, WS₂, WSe₂, SnS₂, SnS, ZrO₂, ZrO, and TiO₂. A frame is disposed over the membrane. In an embodiment, Each of the first inorganic nanotubes includes a plurality of coaxial walls. In an embodiment, each of the first inorganic nanotubes includes 3 to 30 coaxial walls. In an embodiment, at least one coaxial wall of the plurality of coaxial walls is formed of a different material than another coaxial wall of the plurality of coaxial walls.

In an embodiment, the second inorganic nanotubes include a plurality of coaxial walls. In an embodiment, the second inorganic nanotubes surround 3 to 100 first inorganic nanotubes. In an embodiment, the membrane has a thickness ranging from 10 to 100 nm. In an embodiment, the first inorganic nanotubes have an interior diameter ranging from 0.5 nm to 10 nm. In an embodiment, the first inorganic nanotubes are arranged parallel to each other in a cross-sectional view.

Another embodiment of the disclosure includes a pellicle including a membrane disposed over a frame. The membrane includes a plurality of first multiwall nanotubes. Each of the first multiwall nanotubes surrounds a plurality of second multiwall nanotubes. Each of the plurality of second multiwall nanotubes surrounds a third multiwall nanotube. The second multiwall nanotubes and the third multiwall nanotubes are made of different materials. In an embodiment, the second multiwall nanotubes are carbon nanotubes. In an embodiment, the first multiwall nanotubes include one or more of boron nitride, hexagonal boron nitride (h-BN), SiC, MoS₂, MoSe₂, WS₂, WSe₂, SnS₂, SnS, ZrO₂, ZrO, and TiO₂. In an embodiment, each of the first multiwall nanotubes surrounds 3 to 100 second multiwall nanotubes.

It will be understood that not all advantages have been necessarily discussed herein, no particular advantage is required for all embodiments or examples, and other embodiments or examples may offer different advantages.

The foregoing outlines features of several embodiments or examples so that those skilled in the art may better understand the aspects of the present disclosure. Those skilled in the art should appreciate that they may readily use the present disclosure as a basis for designing or modifying other processes and structures for carrying out the same purposes and/or achieving the same advantages of the embodiments or examples introduced herein. Those skilled in the art should also realize that such equivalent constructions do not depart from the spirit and scope of the present disclosure, and that they may make various changes, substitutions, and alterations herein without departing from the spirit and scope of the present disclosure.

What is claimed is:

1. A method of forming a pellicle, comprising:
growing carbon nanotubes (CNTs);
wrapping the CNTs with one or more nanotubes made of a different material; and
removing the CNTs.

2. The method according to claim 1, further comprising growing the CNTs over a filter.

3. The method according to claim 2, further comprising removing the filter.

4. The method according to claim 1, further comprising contacting the CNTs with a frame.

5. The method according to claim 1, wherein the different material includes one or more of boron nitride, hexagonal boron nitride (h-BN), SiC, MoS₂, MoSe₂, WS₂, WSe₂, SnS₂, SnS, ZrO₂, ZrO, and TiO₂.

6. The method according to claim 1, wherein the CNTs are removed by oxidizing the CNTs.

7. The method according to claim 6, wherein oxidizing the CNTs includes heating the CNTs at a temperature ranging from 500 °C to 700 °C.

8. The method according to claim 1, wherein the CNTs include multiwall carbon nanotubes.

9. A method of manufacturing a pellicle, comprising:
forming a plurality of carbon nanotubes,
wherein each of the carbon nanotubes includes one or more walls;
bonding the plurality of carbon nanotubes together to form a nanotube bundle;
forming a first inorganic nanotube surrounding nanotube bundle,
wherein the inorganic nanotube is made of a different material than the carbon nanotubes; and
at least partially removing the nanotube bundle.

10. The method according to claim 9, further comprising forming a second inorganic nanotube on innermost walls of the plurality of nanotubes, wherein the second inorganic nanotubes are made of a different material than the carbon nanotubes.

11. The method according to claim 10, wherein the second inorganic nanotubes include a plurality of coaxial walls.

12. The method according to claim 9, wherein the first inorganic nanotube includes a plurality of coaxial walls.

13. The method according to claim 9, wherein the nanotube bundle is completely removed.

14. A pellicle, comprising:
a membrane including a plurality of inorganic nanotubes,
wherein the membrane does not include carbon nanotubes; and
a frame disposed over the membrane.

15. The pellicle of claim 14, wherein the inorganic nanotubes include one or more of boron nitride, hexagonal boron nitride (h-BN), SiC, MoS₂, MoSe₂, WS₂, WSe₂, SnS₂, SnS, ZrO₂, ZrO, and TiO₂.

16. The pellicle of claim 14, wherein each inorganic nanotube includes a plurality of coaxial walls.

17. The pellicle of claim 16, wherein each inorganic nanotube includes 3 to 30 coaxial walls.

18. The pellicle of claim 17, wherein at least one coaxial wall of the plurality of coaxial walls is formed of a different material than another coaxial wall of the plurality of coaxial walls.

19. The pellicle of claim 14, wherein the membrane has a thickness ranging from 10 to 100 nm.

20. The pellicle of claim 14, wherein the inorganic nanotubes have an interior diameter ranging from 0.5 nm to 10 nm.
